(19) United States
(12) Patent Application Publication
(10) Pub. No.: US 2004/0092126 A1
(43) Pub. Date: May 13, 2004

(54) Method for preventing reworked photoresist from collapsing

(75) Inventors: Zen-Long Yang, Hsinchu (TW); Yi-Fong Tseng, Hsinchu (TW); Ming-Kuan Kao, Hsinchu (TW); Su-Ling Tseng, Hsinchu Hsien (TW); Lung Chen, Hsinchu (TW)

Correspondence Address: SUGHRUE MION, PLLC, 2100 PENNSYLVANIA AVENUE, N.W., SUITE 800, WASHINGTON, DC, 20037, US

(73) Assignee: SILICON INTEGRATED SYSTEMS CORPORATION

(21) Appl. No.: 10/289,432

(22) Filed: Nov. 7, 2002

(51) Int. Cl. H01L 21/302; H01L 21/461

(52) U.S. Cl. 438/725

(57) ABSTRACT

A method for preventing reworked photoresist from collapsing is described. After stripping undesired photoresist off a wafer and before re-performing a lithography process thereon, the wafer is placed in a chemical vapor deposition chamber filled with N₂O gas for a predetermined time to form a nitrogen-rich native oxide layer on the surface of the wafer. Afterwards, reworked photoresist is formed on the nitrogen-rich native oxide layer. The nitrogen-rich native oxide layer restores the moisture and the reflectivity of the surface of the wafer to a predetermined range before performing the photoresist reworking process. Hence, the invention prevents the reworked photoresist from collapsing and improves the fabrication yield.

### BACKGROUND OF THE INVENTION

1. Field of Invention

The invention relates to a semiconductor manufacturing process and, in particular, to a photoresist reworking process that prevents reworked photoresist from collapsing.

2. Related Art

The complementary metal-oxide semiconductor (CMOS), featuring low energy consumption and high density, has become an important element in modem integrated circuits (IC's). In addition to multiple oxidation, doping, and deposition steps, the formation of a CMOS structure further experiences photolithography and etching processes to define the structure in each layer. Since the gate of the CMOS functions as the switch for controlling the CMOS channel effect, the quality of the gate greatly affects the CMOS functions. The gate is normally formed by depositing in order material layers, such as silicon dioxide layers and polysilicon layers, on a silicon substrate and then defining its structure through photolithography and etching processes. After entering the deep submicron processes, the line width of each element becomes very small. In order to obtain gates with a good quality, it is important to have high precision in making and defining each material layer of the gate. Therefore, it is necessary to have good and precise photoresist patterns for ideal etching results.

The photolithography process is a key step in determining the thin-film pattern and impurity areas in each layer when making the IC. The quality of the photolithography technique does not only influence the density and quality of the elements, but also determines the fabrication yield and costs. The basic principle of the photolithography technology is to coat a layer of photoresist material on a wafer. The pattern on the photo mask is transferred to the photoresist layer covering the wafer by exposure and development, forming a protection mask for subsequent etching or ion implantation processes. After the etchings and ion implantation are completed, the photoresist layer is stripped off. The fabrication yield and precision have very close relation with the quality of photoresist. An ideal photolithography process is to successfully transfer the pattern on a photo mask onto the photoresist, and the quality of the photolithography process is determined by the exposure. Since the reflectivity of the wafer surface affects the exposure result, it is of great importance to control the reflectivity of the wafer surface within an appropriate range to ensure a good and precise photoresist pattern.

However, in a deep submicron process, it is not easy to produce a satisfactory photoresist pattern on a polysilicon layer. When the photoresist pattern fails or does not reach a standard, the photoresist on the wafer has to be reworked, removing unsuccessful or unsatisfactory photoresist and re-performing the photolithography process. The common methods for removing photoresist include wet etching and dry etching. The wet etching utilizes an organic or inorganic solution to strip off the photoresist. Commonly used organic solutions include acetone and phenol bases, while the inorganic solutions include sulfuric acid and H₂O₂. The dry etching strips off the photoresist using plasma. Oxygen plasma is often used to perform reactive etching of the photoresist. This is similar to burning reactions, photoresist becoming gas CO, CO₂, and H₂O that are then extracted out using a vacuum system in the plasma reaction chamber. To completely remove the photoresist and avoid residual particles and other substance, left over from plasma reactions, from staying on the wafer surface, the wet and dry etching processes can be combined to perform the photoresist stripping.

After high-temperature burning reactions in the oxygen plasma and soaking in a photoresist removal solution with strong acid, the moisture and the reflectivity of the surface of the wafer will differ from the original ones. When performing photoresist exposure again, the setting parameters of the exposure machine and the reflectivity of surface of the reworked wafer are incompatible, resulting in insufficient or excess exposure. The developed photoresist will then experience deformation or collapsing. Therefore, before re-performing the photolithography process on the reworked wafer, the setting parameters of the exposure machine have to be adjusted to comply with the moisture and reflectivity of the wafer surface. This is to prevent the reworked photoresist from collapsing and inappropriate pattern transfers that will destroy the whole batch of wafers.

However, re-adjusting the manufacturing parameters of the exposure machine elongates the fabrication time, complicating the process and lowering the yield. On the other hand, replacing a whole batch of wafer increases the fabrication cost. Consequently, it is highly desirable to provide a new photoresist reworking method so that the photoresist on the wafer can be reworked using existing semiconductor equipment and manufacturing parameters. The ultimate goals are to prevent photoresist collapse, increase the fabrication yield and reduce the manufacturing cost.

### SUMMARY OF THE INVENTION

As stated before, the moisture and reflectivity on the wafer surface change after the photoresist is removed in the photoresist reworking process, resulting in difficulty in subsequent photolithography process and possibility of photoresist collapse. Performing photoresist reworking on the wafer using the original exposure machine requires re-adjustment of fabrication parameters for each set of reworked wafer surfaces. This increases the manufacturing complexity, lowers the yield and raises fabrication costs. Therefore, the invention provides a new photoresist reworking method to prevent the reworked photoresist from collapsing.

An objective of the invention is to provide a method for preventing reworked photoresist from collapsing. After removing the photoresist and before performing the photolithography process again, N₂O is used to process the wafer surface so that the moisture and reflectivity of the wafer surface are restored back to the appropriate range before reworking. In this case, the manufacturing parameters on the exposure machine need not to be adjusted again.

Another objective of the invention is to provide a photoresist method that can prevent photoresist from collapsing due to the changes in the moisture and reflectivity of the surface of the wafer after photoresist reworking.

Pursuant to the above-mentioned objectives, the invention discloses a method suitable for a semiconductor substrate, which is first formed with a first photoresist pattern. This method requires the steps of removing the first photoresist pattern and exposing the semiconductor substrate in N₂O for a predetermined time, thus forming a native oxide layer. The step of removing the first photoresist pattern employs the oxygen plasma and/or wet etching.

The invention also provides a photoresist reworking method that includes the steps of providing a semiconductor substrate containing a polysilicon layer, forming a first photoresist pattern in the polysilicon layer, removing the first photoresist pattern, exposing the semiconductor substrate in N₂O for a predetermined time to form a native oxide layer on the surface of the polysilicon layer, and forming a second photoresist pattern on the polysilicon layer. An anti-reflection layer can be further formed on the polysilicon layer. The step of removing the first photoresist pattern employs the oxygen plasma and wet etching.

### BRIEF DESCRIPTION OF THE DRAWINGS

These and other features, aspects and advantages of the invention will become apparent by reference to the following description and accompanying drawings which are given by way of illustration only, and thus are not limitative of the invention, and wherein:

FIG. 1 is a schematic cross-sectional view of the manufacturing process for making the gate of a transistor;

FIG. 2 is a flowchart of the photoresist reworking process according to an embodiment of the invention; and

FIG. 3 is a flowchart of the photoresist reworking process according to another embodiment of the invention.

### DETAILED DESCRIPTION OF THE PREFERRED EMBODIMENT

The following description discloses a method for preventing reworked photoresist from collapsing with reference to preferred embodiments.

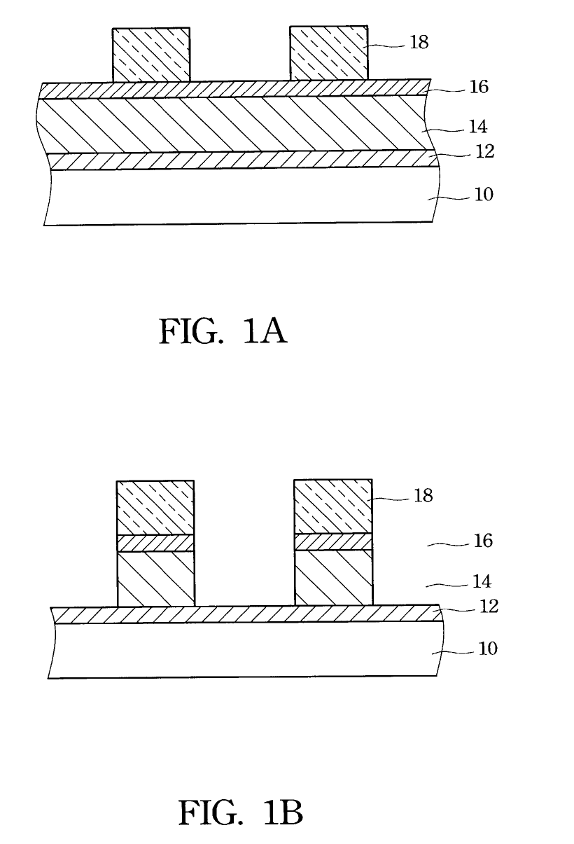

As shown in FIG. 1, a semiconductor substrate 10 is formed with a gate oxide layer 12. Preferably, the gate oxide layer 12 is a layer of SiO₂ on the substrate surface 10 formed using the high-temperature oxidation method with a temperature in the range of 1000° C. to 1300° C. Afterwards, the gate oxide layer 12 is formed using chemical vapor deposition (CVD) with a polysilicon layer 14, whose thickness is between about 500 Å and 5000 Å and is preferably about 2000 Å. The polysilicon layer 14 is then covered with an anti-reflective coating (ARC) 16. Preferably, the ARC 16 is formed using the CVD to deposit a layer of SiON on the polysilicon layer 14. The thickness of the ARC 16 is between about 500 Å and 800 Å and is preferably about 550 Å. The reflectivity of the ARC 16 is about 1.5.

Subsequently, an appropriate positive or negative photoresist layer 18 is formed on the ARC 16. The material of the photoresist layer 18 may be an appropriate photoresist. The photoresist layer 18 can be applied on the ARC 16 using any method such as spin coating. The conventional exposure and development techniques are then employed to define a desired pattern on the photoresist layer 18.

When the photoresist pattern is not completely satisfactory (e.g. incorrect shape or size and deformed or destroyed photoresist patterns), the photoresist has to be reworked. That is, the unsatisfactory photoresist pattern is removed from the wafer surface and a new photoresist pattern is formed thereon. The usual method of removing the photoresist is to place the wafer in an Asher photoresist strip, where oxygen plasma with a temperature around 240° C. is used to strip off the photoresist. The wafer is then immersed in a photoresist removal solution containing sulfuric acid, H₂O₂, and water to completely remove the residual photoresist and oxygen plasma particles. After the high-temperature plasma processing and reactions in the strong acid solution, the structure on the wafer surface is changed so that its moisture and reflectivity are significantly changed. At the moment, performing exposure on the reworked photoresist using the predetermined manufacturing parameters of the original exposure machine is likely to result in deformation or collapse of the reworked photoresist due to insufficient or excess exposure. Therefore, the Photolithographic department in a semiconductor fab has to adjust the manufacturing parameters for each batch of wafers that requires reworking in order to form an ideal reworked photoresist on the wafer while avoiding photoresist collapses.

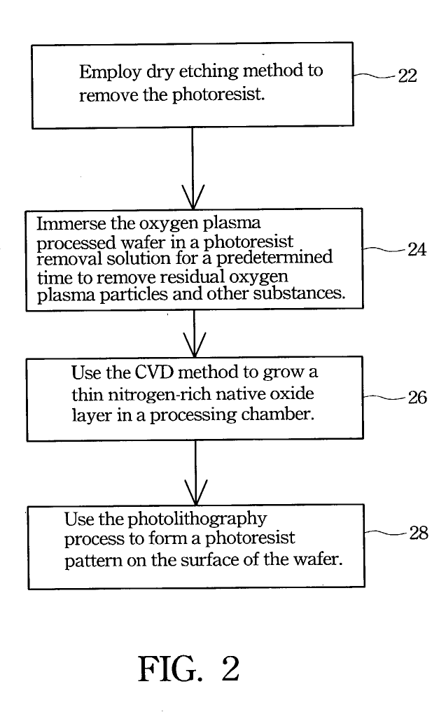

To avoid re-adjusting manufacturing parameters of the exposure machine each time after photoresist reworking and the decreasing yield problem due to the collapses of reworked photoresist, the invention provides a photoresist reworking procedure to prevent the reworked photoresist from collapsing. As shown in FIG. 2, the dry etching method is employed to remove the photoresist in step 22. In a preferred embodiment of the invention, the wafer is placed in oxygen plasma with a temperature of 240° C. to perform dry etching. In step 24, the oxygen plasma processed wafer is soaked in a photoresist removal solution consisted of sulfuric acid, H₂O₂, and water for a predetermined time, completely removing residual oxygen plasma particles and other substances.

The CVD method is then used in step 26. The wafer is placed inside a processing chamber containing N₂O for a predetermined time, growing a thin nitrogen-rich native oxide layer. The processing time for this step is between about 5 seconds and 15 seconds and is preferably about 10 seconds. The temperature of the gas inside the processing chamber is between about 350° C. and 500° C. and preferably is about 400° C. The flux of the N₂O gas is between about 50 sccm and 100 sccm.

Finally, the conventional photolithography process is further employed in step 28 to form a photoresist pattern on the surface of the wafer. Processed using N₂O gas, the reflectivity of SiON on the wafer surface is more stable and becomes the same as that before reworking. Consequently, the reworked wafer can be further processed on the original exposure machine using the original manufacturing parameters without re-adjustment. The reworked photoresist will not collapse, reducing the number of reworking times and fabrication costs.

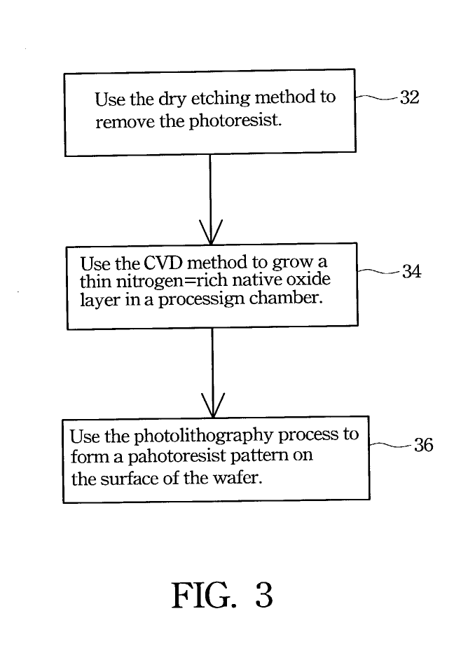

In another embodiment of the invention, the photoresist removal step employs only the oxygen plasma. With reference to FIG. 3, the dry etching method is employed to remove the photoresist in step 32 by placing the wafer in an about 240° C. oxygen plasma. The CVD method is then used in step 34. The wafer is placed in a processing chamber containing N₂O for a predetermined time, growing a thin nitrogen-rich native oxide layer. The processing time for this step is between about 5 seconds and 15 seconds, and is preferably about 10 seconds. The temperature inside the processing chamber is between about 350° C. and 500° C., and is preferably about 400° C. The flux of the N₂O gas is between about 50 sccm and 100 sccm. The reflectivity of the N₂O processed wafer surface becomes more stable and agrees with that of the wafer surface before photoresist reworking. Consequently, the reworked wafer can be further processed on the original exposure machine using the original manufacturing parameters without re-adjustment. Finally, the conventional photolithography process is used in step 36 to form again a photoresist pattern on the wafer surface.

In the following text, wafers processed by the disclosed method and the conventional method are compared and the results listed in Table 1. In the experiment, the test wafers are divided into three sets; a polysilicon layer and a photoresist layer are formed in order on the surfaces of the wafers in each set. The wafers in the first set undergo oxygen plasma photoresist etching at a temperature of about 240° C. The wafers are then immersed in a photoresist removal solution consisted of sulfuric acid, H₂O₂, and water for wet etching. Finally, a photoresist pattern is formed on the polysilicon layer. For the wafers of the second set, after undergoing oxygen plasma photoresist etching at a temperature of about 240° C., the wafers are then immersed in a photoresist removal solution comprising sulfuric acid, H₂O₂, and water for wet etching. Afterwards, the wafers are placed in a deposition reaction chamber containing about 400° C. N₂O gas for about 10 seconds, thus forming a thin native oxide layer on the polysilicon layer. Finally, a photoresist pattern is formed on the polysilicon layer. For the wafers of the third set, after undergoing oxygen plasma photoresist etching at a temperature of about 240° C., the wafers are placed in a deposition reaction chamber containing about 400° C. N₂O gas for about 10 seconds, thus forming a thin native oxide layer on the polysilicon layer. We use a photo mask detector KLA to perform after development inspection (ADI) on the wafer surfaces in each set.

TABLE 1
(Unit: Å)

| | | Second Set | |
|---|---|---|---|
| | | (dry + wet | Third Set |
| | First Set | photoresist | (dry photoresist |
| | (dry + wet photoresist | etching + N₂O | etching + N₂O |
| | etching) | processing) | processing) |
| Photoresist | Yes | No | No |
| collapses | | | |

From the experiment results, one sees that the wafers in the first set have the problem of serious photoresist collapses because they are not processed with N₂O gas. The wafers in the second set further experience 10 seconds of N₂O processing after oxygen plasma and wet etching. The moisture is brought away by N₂O and a nitrogen-rich native oxide layer if formed on the wafer surface. The moisture and reflectivity of the wafer surface are restored back to an appropriate range before reworking. Therefore, the reworked photoresist thus processed does not collapse. Similarly, the wafers in the third set further experience about 10 seconds of N₂O processing after oxygen plasma etching. The moisture and reflectivity of the wafer surface are also restored back to an appropriate range before reworking. No photoresist collapses occur in this case, either.

From the above-disclosed embodiments, it is easy to see that when reworking photoresist according to the invention, the wafer surface has to be processed in N₂O gas for about 10 seconds after wet and/or wet photoresist etching and before the photolithography process. This can restore the moisture and reflectivity of the wafer surface back to the appropriate range before reworking. Therefore, the same manufacturing parameters can be kept for the original exposure machine to prevent reworked photoresist from collapsing. In summary, the disclosed photoresist reworking method can effectively prevent reworked photoresist from collapsing.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A method for preventing reworked photoresist from collapsing for a semiconductor substrate formed with a first photoresist pattern thereon, the method comprising the steps of:
removing the first photoresist pattern;
exposing the semiconductor substrate in N₂O for a predetermined time to form a native oxide layer on a surface thereof; and
forming a second photoresist pattern.

2. The method of claim 1, wherein the first photoresist pattern is removed by oxygen plasma.

3. The method of claim 1, wherein the first photoresist pattern is removed by wet etching.

4. The method of claim 1, wherein the first photoresist pattern is removed by both oxygen plasma and wet etching.

5. The method of claim 1, wherein the predetermined time for exposing the semiconductor substrate in N₂O is between about 5 seconds and 15 seconds.

6. The method of claim 1, wherein the predetermined time for exposing the semiconductor substrate in N₂O is about 10 seconds.

7. The method of claim 1, wherein a flux of N₂O is between about 50 sccm and 100 sccm.

8. The method of claim 1, wherein a processing temperature of N₂O is between about 300° C. and 500° C.

9. The method of claim 1, wherein a processing temperature of N₂O is about 400° C.

10. A photoresist reworking method comprising the steps of:
providing a semiconductor substrate containing a polysilicon layer;
forming a first photoresist pattern on the polysilicon layer;
removing the first photoresist pattern;
exposing the semiconductor substrate in N₂O for a predetermined time to form a native oxide layer on a surface thereof; and
forming a second photoresist pattern on the native oxide layer.

11. The method of claim 10, wherein the polysilicon layer is further formed with an anti-reflection coating.

12. The method of claim 10, wherein the first photoresist pattern is removed by oxygen plasma.

13. The method of claim 10, wherein the first photoresist pattern is removed by wet etching method.

14. The method of claim 10, wherein the first photoresist pattern is removed by both oxygen plasma and wet etching.

15. The method of claim 10, wherein the predetermined time for exposing the semiconductor substrate in N₂O is between about 5 seconds and 15 seconds.

16. The method of claim 10, wherein the predetermined time for exposing the semiconductor substrate in N₂O is about 10 seconds.

17. The method of claim 10, wherein a flux of N₂O is between about 50 sccm and 100 sccm.

18. The method of claim 10, wherein a processing temperature of N₂O is between about 300° C. and 500° C.

19. The method of claim 10, wherein a processing temperature of N₂O is about 400° C.
